(19) United States
(12) Patent Application Publication
(10) Pub. No.: US 2024/0389324 A1
(43) Pub. Date: Nov. 21, 2024

(54) SEMICONDUCTOR STRUCTURE, FABRICATION METHOD THEREOF, AND MEMORY SYSTEM

(71) Applicant: YANGTZE MEMORY TECHNOLOGIES CO., LTD., Wuhan (CN)

(72) Inventors: Zhibin Liu, Wuhan (CN); Jingtao Xie, Wuhan (CN); Wenxi Zhou, Wuhan (CN)

(21) Appl. No.: 18/538,860

(22) Filed: Dec. 13, 2023

Related U.S. Application Data
(63) Continuation of application No. PCT/CN23/94214, filed on May 15, 2023.

(51) Int. Cl. H10B 43/27; H10B 41/27; H10B 41/35; H10B 43/35

(52) U.S. Cl. CPC H10B 43/27; H10B 41/27; H10B 41/35; H10B 43/35

(57) ABSTRACT

A semiconductor structure, a fabrication method thereof and a memory system are provided. The method includes: forming a stack of layers having a first surface; forming a channel structure extending through the stack of layers in a stacking direction, and comprising a channel layer and a plug structure electrically connected with the channel layer, wherein the plug structure is located close to the first surface and comprising an exposed surface; oxidizing the exposed surface of the plug to form a protruding structure, a surface of the protruding structure protruding above the first surface; forming an upper select gate layer on the first surface, the upper select gate layer covering the protruding structure; and forming an upper select channel structure extending through the upper select gate layer and the protruding structure in the stacking direction, and being in contact with the plug structure.

### CROSS-REFERENCE TO RELATED APPLICATIONS

This application is a continuation of International Application No. PCT/CN2023/094214, filed on May 15, 2023, the content of which is incorporated herein by reference in its entirety.

### TECHNICAL FIELD

The present disclosure relates to the field of semiconductor technology, and in particular to a semiconductor structure, a fabrication method thereof and a memory system.

### BACKGROUND

Three-dimensional memories (e.g., 3D NAND memories) are an emerging type of memories each having multiple tiers of memory cells stacked vertically. Based on this technology, a storage apparatus with a capacity increased by a few times can be made in contrast to using congeneric NAND technology. This technology can support higher storage capacity within a smaller space, so that cost can be saved substantially, power consumption can be lowered and performance can be improved greatly.

In 3D NAND technology, the select transistors corresponding to the upper select gates may be formed separately to satisfy the design of the small sized select transistors and improve storage density. However, the bottom topography of the select transistors fabricated using existing methods may cause potential drift and thus influence reliability of memory.

### SUMMARY

The present disclosure provides a semiconductor structure, a fabrication method thereof and a memory system that can avoid potential drift caused by the bottom topography of select transistors, which is favorable to improve reliability of memory.

In one aspect, examples of the present disclosure provide a method of fabricating a semiconductor structure, the method including: forming a stack of layers and a channel structure, the stack of layers including a first surface, the channel structure extending through the stack of layers in the stacking direction and including a channel layer and a plug structure electrically connected with the channel layer, and the plug structure being located at a side of the channel layer close to the first surface and including an exposed surface; oxidizing the exposed surface to form protruding structure thereon, the surface of the protruding structure on the side away from the plug structure protruding above the first surface; forming an upper select gate layer on the first surface, the upper select gate layer covering the protruding structure; and forming an upper select channel structure extending through the upper select gate layer and to the plug structure in the stacking direction.

In another aspect, examples of the present disclosure provide a semiconductor structure that includes: a stack structure; a channel structure extending through the stack structure in the stacking direction, the channel structure including a channel layer and a plug structure electrically connected with the channel layer, and the plug structure being located at one end of the channel layer; a protruding structure being located on the side of the plug structure away from the channel layer and protruding toward the side away from the plug structure; an upper select gate layer located on the side of the stack structure close to the plug structure and covering the protruding structure; and an upper select channel structure extending through the upper select gate layer in the stacking direction and to the plug structure.

In yet another aspect, examples of the present disclosure further provide a memory system including at least one memory including at least one semiconductor structure described above; and a controller coupled with the at least one memory and configured to control data storage thereof.

In the semiconductor structure, the fabrication method thereof and the memory system provided in examples of the present disclosure, a stack of layers and a channel structure are formed, with the channel structure extending through the stack of layers in the stacking direction and including a channel layer and a plug structure electrically connected with the channel layer; the plug structure is located at the side of the channel layer close to the first surface and has an exposed surface; the exposed surface is oxidized to form protruding structure thereon and the surface of the protruding structure on the side away from the plug structure protrudes above the first surface; an upper select gate layer is formed on the first surface and covers the protruding structure; an upper select channel structure is formed and it extends through the upper select gate layer and to the plug structure in the stacking direction, so that sharp corners are prevented from being formed by the upper select channel structure in the upper select gate layer and the bottom surface of the upper select gate layer and in turn the problem of potential drift caused by local electric field with too high a magnitude can be solved.

### BRIEF DESCRIPTION OF DRAWINGS

In order to explain technical solutions in examples of the present disclosure more clearly, accompanying drawings required for describing the examples will be described briefly hereafter. It is obvious that the drawings described below are only some examples of the present disclosure and other drawings can be obtained according to those drawings without any creative work.

FIG. 1 is a flowchart illustrating a method of fabricating a semiconductor structure provided in an example of the present disclosure;

FIGS. 2A to 2K are cross-sectional structure diagrams of a semiconductor structure at different process operations in an example of the present disclosure;

FIG. 3A is an enlarged structural diagram of the part M1 in FIG. 2C;

FIG. 3B is an enlarged structural diagram of the part M2 in FIG. 2D;

FIG. 3C is an enlarged structural diagram of the part M3 in FIG. 2J;

FIGS. 4A to 4C are some other cross-sectional structure diagrams of a semiconductor structure at different process operations provided in an example of the present disclosure;

FIGS. 5A and 5B are cross-sectional structure diagrams of yet another semiconductor structure at different process operations provided in an example of the present disclosure;

FIG. 6 is a structural diagram of an example system provided in an example of the present disclosure;

FIG. 7 is structural diagram of an example memory card provided in an example of the present disclosure;

FIG. 8 is a structural diagram of an example solid state drive (SSD) provided in an example of the present disclosure; and

FIG. 9 is a structural diagram of a memory provided in an example of the present disclosure.

### DETAILED DESCRIPTION

The present disclosure will be described in detail hereafter with reference to accompanying drawings and examples. It is particularly noted that the following examples are only used to illustrate the present disclosure and not to define its scope. Likewise, the following examples are only some, not all, of the examples of the present disclosure, and all other examples obtained by those of ordinary skills in the art without any creative work fall within the scope claimed by the present disclosure.

In the description herein, it is understood that orientation and position relationships indicated by terms “center”, “lateral”, “upper”, “lower”, “left”, “right”, “vertical”, “horizontal”, “top”, “bottom”, “inner” and “outer” are those based on the drawings and only for the purpose of describing and simplifying the description. There is no indication or implication that the devices or elements referred to must have any particular orientations and positions, or be constructed or operated in any particular orientations and positions. As a result, they should not be understood as limitation for the present disclosure. Moreover, the terms “first”, “second” etc. are only used for the purpose of description and should not be understood to indicate or imply relative importance or to designate the number of the referenced technical features implicitly. Therefore, a feature qualified by “first” or “second” may include explicitly or implicitly one or more instances of the feature.

In the description herein, it is noted that terms “mount”, “interconnect” and “connect” should be explained broadly, and they include, for example, fixed connection, removable connection or integral connection; mechanical connection or electrical connection; direct interconnection or interconnection with intermediate medium; or inner communication of two elements, unless otherwise specified or limited expressly. The specific meaning of the above-mentioned terms in the present disclosure will be understood by those of ordinary skills in the art depending on specific circumstances.

It should be understood that the meaning of terms “on,” “over,” and “above” herein should be interpreted in the broadest manner such that “on” not only means “on” something without any intermediate feature or layer (i.e., directly on something) but also includes the meaning of “on” something with an intermediate feature or layer therebetween.

Terms used herein are only for the purpose of describing specific examples without any intention of limiting them. Singular forms such as “a”, “an”, and “the” used herein are also intended to include plural forms, unless otherwise noted in the context. The phrase “a plurality of” means two or more unless otherwise specified. It is also understood that terms “include” and/or “comprise” used herein designate existence of the stated features, integers, steps, operations, elements and/or assemblies without excluding existence or addition of one or more other features, integers, steps, operations, elements, assemblies and/or any combination thereof.

Examples of the present disclosure provide a semiconductor structure, a fabrication method thereof and a memory system.

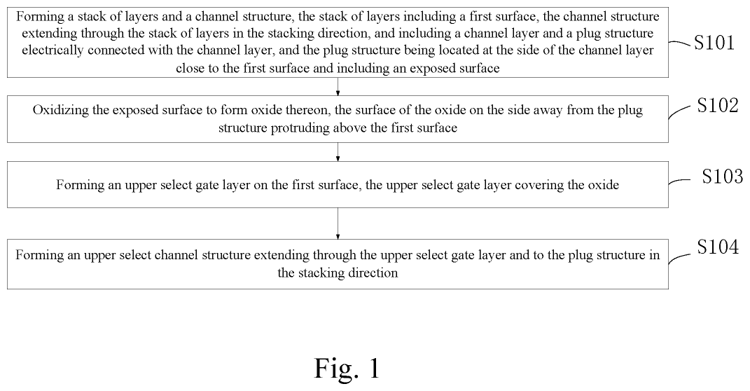

Refer to FIG. 1, which is a flowchart of a method of fabricating a semiconductor structure provided in an example of the present disclosure. The method of fabricating a semiconductor structure may include the following operations S101-S104.

At operation S101, a stack of layers and a channel structure are formed. The stack of layers includes a first surface. The channel structure extends through the stack of layers in the stacking direction, and includes a channel layer and a plug structure electrically connected with the channel layer. The plug structure is located at the side of the channel layer close to the first surface and includes an exposed surface.

At operation S102, the exposed surface is oxidized to form protruding structure thereon. The surface of the protruding structure on the side away from the plug structure protrudes above the first surface.

At operation S103, an upper select gate layer is formed on the first surface and covers the protruding structure.

At operation S104, an upper select channel structure is formed, the upper select channel structure extending through the upper select gate layer and to the plug structure in the stacking direction.

It should be understood that the operations shown in the above-described fabrication method are not exclusive and other operations may be performed before, after or between any one(s) of the shown operations.

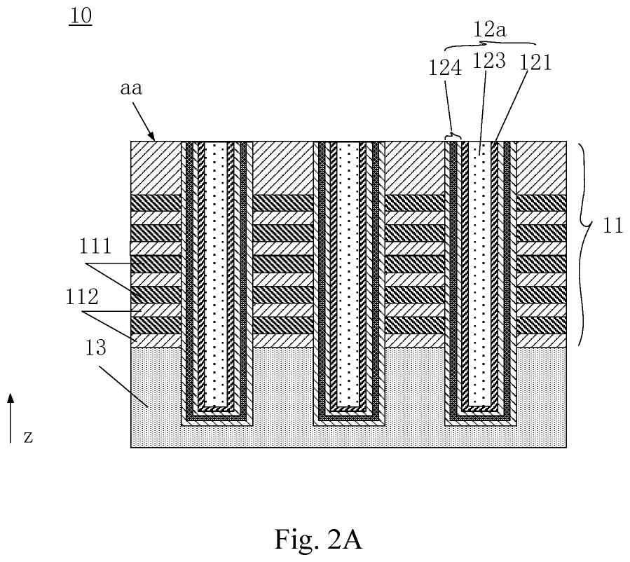

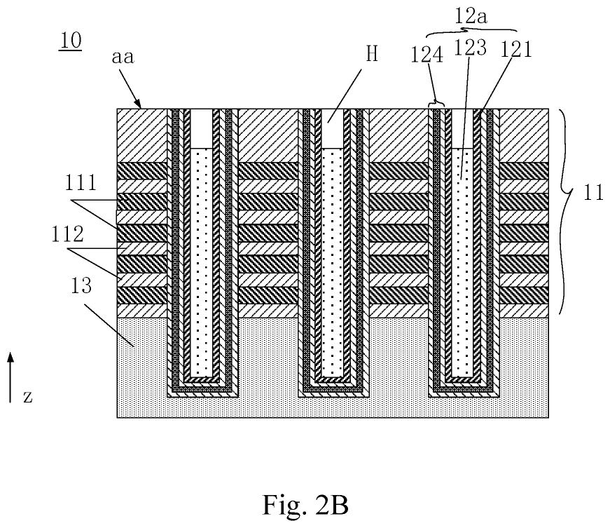

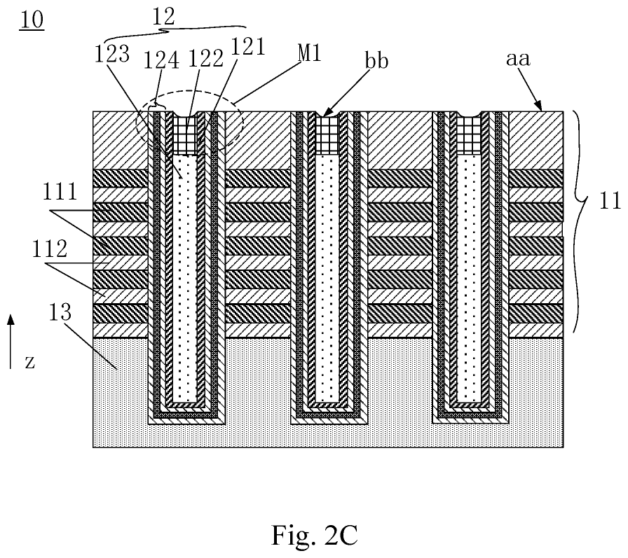

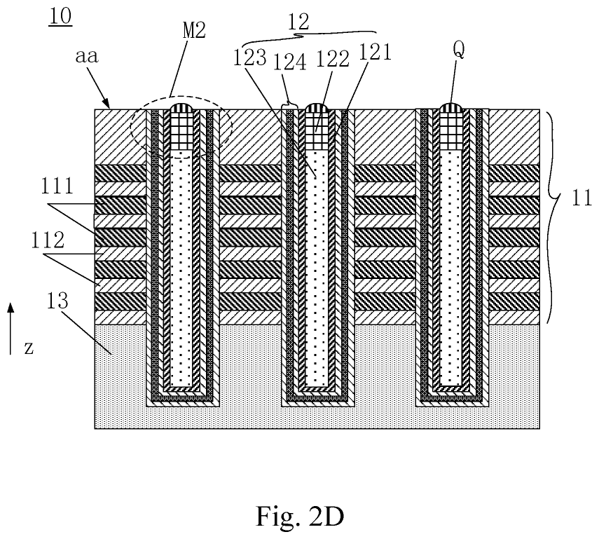

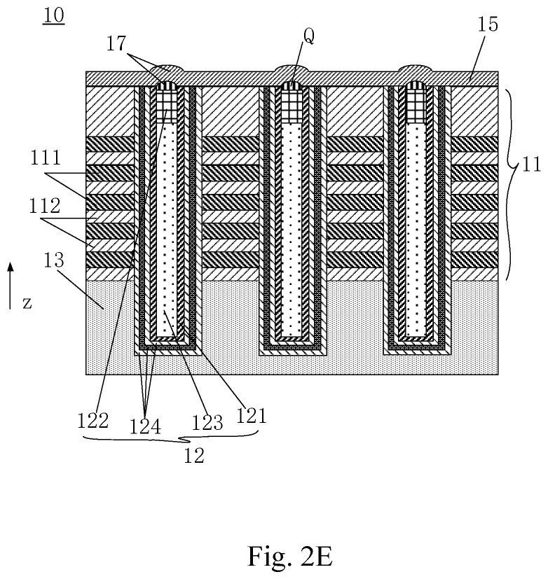

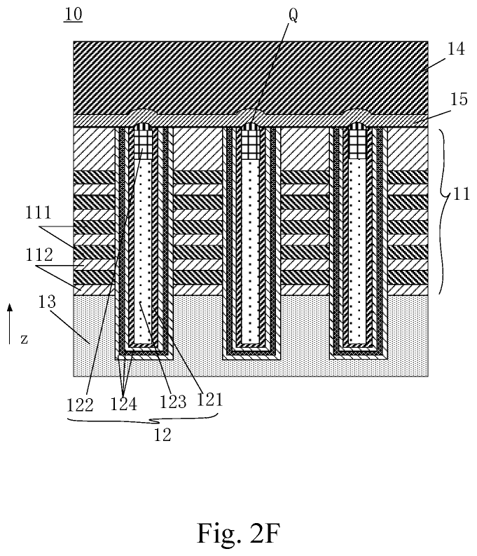

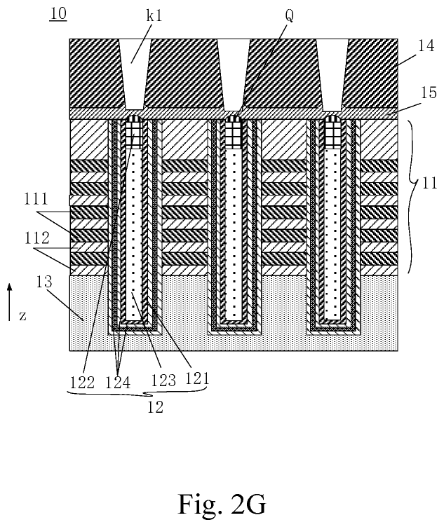

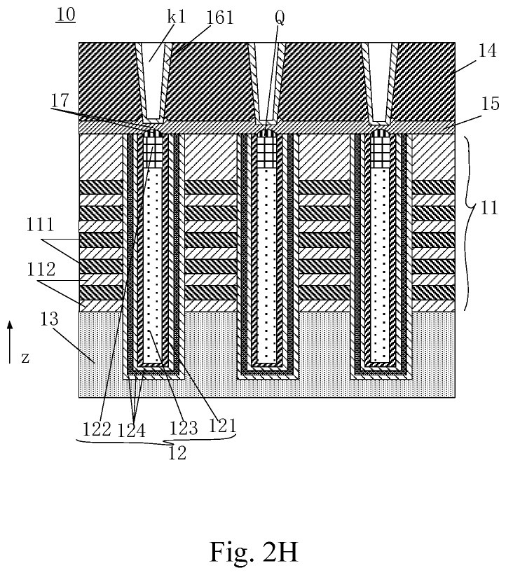

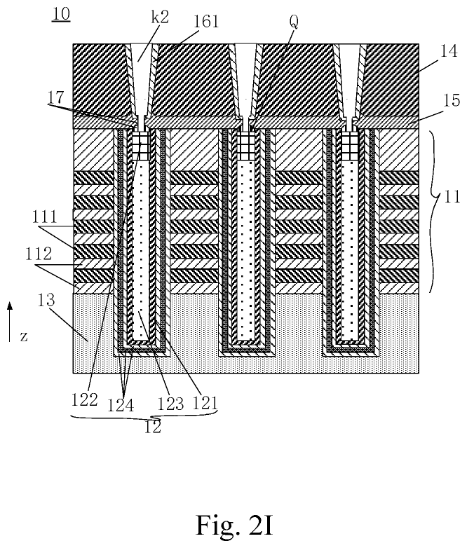

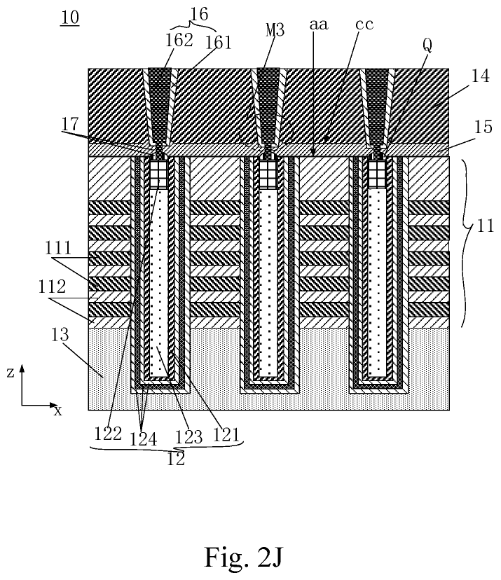

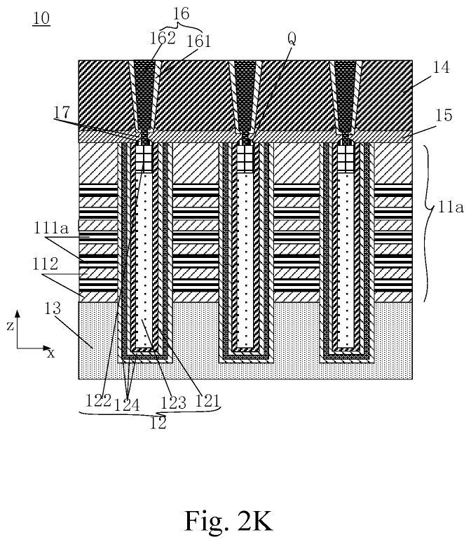

Refer to FIGS. 2A to 2K, which are cross-sectional structure diagrams of a semiconductor structure 10 at different process operations provided in an example of present disclosure. The above-mentioned operations S101-S104 will be described hereafter in connection with FIGS. 2A to 2K.

At operation S101, a stack of layers 11 and a channel structure 12 are formed. The stack of layers 11 includes a first surface aa. The channel structure 12 extends through the stack of layers 11 in the stacking direction Z, and includes a channel layer 121 and a plug structure 122 electrically connected with the plug structure 121. The plug structure 122 is located at the side of the channel layer 121 close to the first surface aa and includes an exposed surface bb.

Herein, with reference to FIG. 2C mentioned above, the channel layer 121 includes polysilicon and the plug structure 122 includes a conductive material, for example, any one or combination of polysilicon and metal materials such as tungsten, cobalt, copper, or aluminum, etc. The stack of layers 11 includes gate sacrificial layers 111 and gate insulating layers 112 alternating with the gate sacrificial layers 111 and the stacking direction z is the direction, in which the gate sacrificial layers 111 and gate insulating layers 112 are stacked.

The stack of layers 11 may be formed using any suitable thin film deposition process such as chemical vapor deposition (CVD), physical vapor deposition (PVD), atomic layer deposition (ALD) or any combination thereof. The gate sacrificial layers 111 may include silicon nitride and the gate insulating layers 112 may include silicon protruding structure. The thicknesses of the gate insulating layers 112 may not be the same. For example, the thickness of the top gate insulating layer 112 may be larger than the thickness of each of the other gate insulating layers 112.

It can be readily understood that the stack of layers 11 is formed on a substrate 13 and the channel structure 12 extends through the stack of layers 11 into the substrate 13. The substrate 13 may include at least one of single crystal silicon (Si), single crystal germanium (Ge), III-V compound semiconductor materials, II-VI compound semiconductor materials or any other semiconductor materials known in the art.

In some implementations, with reference to FIGS. 2A, 2B and 2C, the above-mentioned operation S101 may for example include: forming a memory channel structure 12a extending through the stack of layers 11 in the stacking direction z, the memory channel structure 12a including a channel layer 121 and a filling layer 123 surrounded by the channel layer 121, and the stack of layers 11 including the first surface aa; removing a portion of the filling layer 123 close to the first surface aa in the memory channel structure 12a to obtain a space H; depositing a layer of conductive material over the first surface aa with the layer of conductive material filling the space H; and removing the conductive material outside the space H to form the plug structure 122, resulting in the channel structure 12.

Herein, the filling layer 123 is located on the side of the channel layer 121 away from the stack of layers 11 and includes an insulating material, for example, protruding structure such as silicon protruding structure, and the conductive material may include any one or combination of polysilicon and metal materials such as tungsten, cobalt, copper, or aluminum.

In an example, the space H may be obtained by removing a portion of the filling layer 123 with dry etching or wet etching and may have its depth controlled by the duration of the etching and concentration of the etchant. The redundant conductive material may be removed by chemical mechanical polishing (CMP). The conductive material filled in the space H may be used as a plug structure 122. In other words, the plug structure 122 is formed at the top end of the memory channel structure 12a, and the plug structure 122 together with the memory channel structure 12a left after removing the portion of the filling layer 123 function as the channel structure 12.

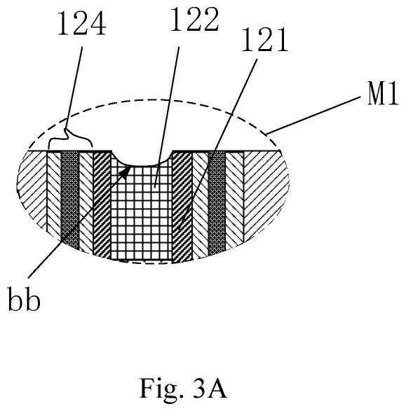

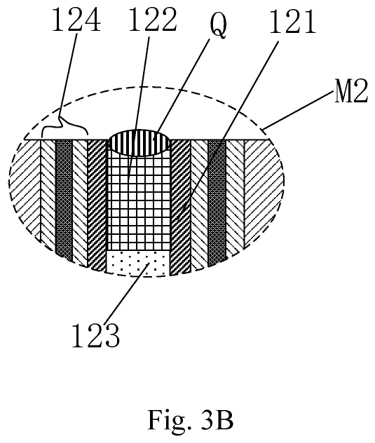

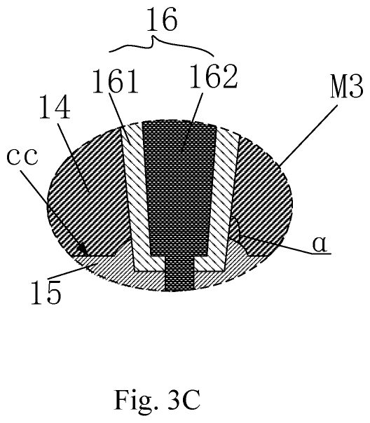

With continuous reference to FIG. 2B, FIG. 2C and FIG. 3A (an enlarged structural diagram of the part M1 in FIG. 2C), it is to be noted that, after the CMP process, a recess is formed finally at the top end of the plug structure 122, i.e., the exposed surface bb of the plug structure 122 is recessed toward the side of the filling layer 123.

In some other implementations, with continuous reference to FIGS. 2A to 2C and FIG. 3A, the operation of forming the memory channel structure 12a extending through the stack of layers 11 in the stacking direction z includes: forming a memory channel hole extending through the stack of layers 11 in the stacking direction z; forming a memory functional layer 124 over the inner wall of memory channel hole; forming a channel layer 121 on the side of memory functional layer 124 away from the inner wall; and forming a filling layer 123 on the side of channel layer 121 away from the memory functional layer 124, the filling layer 123 filling up the memory channel hole.

Herein, the memory functional layer 124 may be an ONO film including silicon protruding structure, silicon nitride and silicon protruding structure. In the channel structure 12, the height of the memory functional layer 124 in the stacking direction z is larger than the height of the filling layer 123 in the stacking direction z.

At operation S102, the exposed surface bb is oxidized, so that protruding structure Q is formed on the exposed surface bb. The surface of the protruding structure Q on the side away from the plug structure 122 protrudes above the first surface aa.

Herein, forming protruding structure Q on the exposed surface bb mainly means converting the exposed portion of the plug structure 122 into protruding structure Q through oxidization. With reference to the above-mentioned FIGS. 2C and 2D and FIG. 3B (an enlarged structural diagram of the part M2 in FIG. 2D), the material of the protruding structure Q is determined by the material of the plug structure 122, e.g., when the plug structure 122 is polysilicon, the protruding structure Q is silicon protruding structure. During oxidization, the volume of the protruding structure Q grows gradually, so that the top end of the plug structure 122 transforms from a recessed shape into a protruding shape.

In some other implementations, in order to speed up oxidization, the fabrication method of the semiconductor structure 10 may further include doping the exposed surface bb before its oxidization. Herein, ions promoting oxidization may be doped and the higher the doping concentration is, the faster the protruding structure Q forms and the bigger its volume is.

At operation S103, an upper select gate layer 14 is formed on the first surface aa with the protruding structure Q being covered by it.

Herein, with reference to FIGS. 2D, 2E and 2F, the upper select gate layer 14 may cover the protruding structure Q indirectly, i.e., there may be other films disposed therebetween. The upper select gate layer 14 may include a conductive material such as polysilicon and have a relatively large thickness in the stacking direction z.

In an example, before the above-mentioned operation S103, the fabrication method of the semiconductor structure 10 may further include: forming an etch stop layer 15 on the first surface aa, the etch stop layer 15 covering the protruding structure Q.

At this point, the protruding structure Q and the etch stop layer 15 between the protruding structure Q and the upper select gate layer 14 may form protruding structures 17 and the above-mentioned operation S103 may for example include forming the upper select gate layer 14 on the side of the etch stop layer 15 away from the stack of layers 11.

Herein, after formation of the protruding structure Q, the etch stop layer 15 may be formed first and then the upper select gate layer 14 is formed. The etch stop layer 15 may include an insulating material such as silicon protruding structure and is different from the upper select gate layer 14 in material. In the stacking direction z, the thickness of the etch stop layer 15 is relatively small, e.g., smaller than the thickness of the upper select gate layer 14 and the thickness of the top gate insulating layer 112.

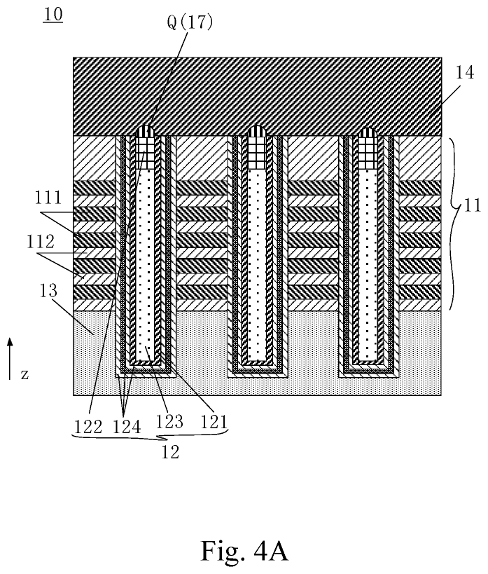

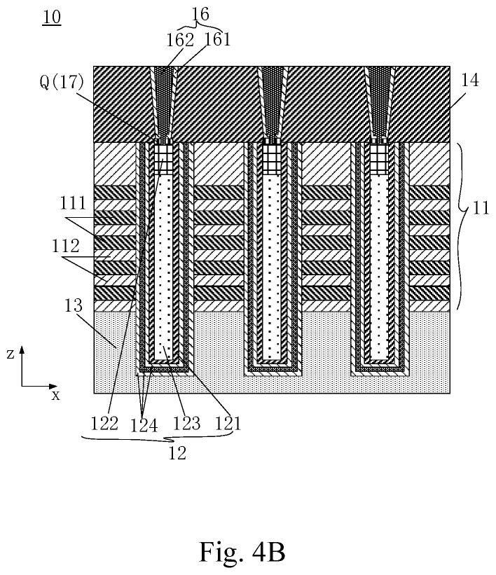

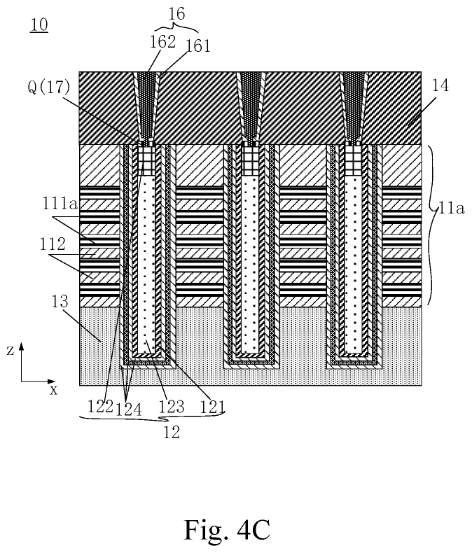

In some implementations, the upper select gate layer 14 may cover the protruding structure Q directly, i.e., there is no other film disposed therebetween. For example, Refer to FIG. 2D again and to FIGS. 4A to 4D, which are some other cross-sectional structure diagrams of the semiconductor structure 10 at different process operations provided in an example of the present disclosure. Herein, it can be seen from the above-mentioned FIG. 2D and FIG. 4A, after formation of the protruding structure Q, the upper select gate layer 14 may be formed directly and at this point the protruding structure Q can serve as the protruding structure 17 immediately.

In some implementations, with continuous reference to FIG. 2F or FIG. 4A, the top surface of the protruding structure Q protrudes above the top surface of the memory functional layer 124, i.e., the spacing between the surface of the protruding structure Q on the side close to the upper select gate layer 14 and the surface of the plug structure 122 on the side close to the upper select gate layer 14 is larger than the spacing between the surface of the memory functional layer 124 on the side close to the upper select gate layer 14 and the surface of the plug structure 122 on the side close to the upper select gate layer 14.

In some implementations, with continuous reference to FIG. 2F or FIG. 4A, in channel structure 12, the top surface of the memory functional layer 124 is above the top surface of the filling layer 123, i.e., the spacing between the surface of the memory functional layer 124 on the side close to the upper select gate layer 14 and the surface of the upper select gate layer 14 on the side away from the stack of layers 11 is smaller than the spacing between the surface of the filling layer 123 on the side close to the upper select gate layer 14 and the surface of the upper select gate layer 14 on the side away from the stack of layers 11.

At operation S104, an upper select channel structure 16 is formed, the upper select channel structure 16 extending through the upper select gate layer 14 and to the plug structure 122 in the stacking direction z.

Herein, with reference to FIGS. 2G to 2J or FIGS. 4A and 4B, the upper select channel structure 16 may include an insulating layer 161 and a conductive layer 162 with the conductive layer 162 being located on the side of the insulating layer 161 away from the upper select gate layer 14 and electrically connected with the plug structure 122. The insulating layer 161 may include a protruding portion such as silicon protruding portion and the conductive layer 162 may be any one or combination of tungsten, cobalt, copper, aluminum, silicon or doped crystalline silicon.

In some implementations, the upper select channel structure 16 may be formed by etching a hole extending through the upper select gate layer 14 and to the plug structure 122 in the stacking direction z, forming an insulating layer 161 over the sidewall of the etched hole and filling a conductive layer 162 into the etched hole.

In some implementations, the upper select channel structure 16 may be formed in any other way. For example, with continuous reference to FIGS. 2G to 2J, the above-mentioned operation S104 may for example include: forming, using a first etching, a first hole k1 extending through the upper select gate layer 14 in the stacking direction z; forming an insulating layer 161 over the inner wall of the first hole k1; forming, using a second etching and through the first hole k1, a second hole k2 extending through the upper select gate layer 14 and the insulating layer 161 and to the plug structure 122 in the stacking direction z; and filling a conductive layer 162 in the second hole k2, resulting in the upper select channel structure 16.

Herein, the first etching includes dry etching or wet etching and may use the etch stop layer 15 or protruding structure Q as the stop layer and the second etching may include punch etching. After the first etching, the first hole k1, in addition to extending through the upper select gate layer 14, usually extends further into the etch stop layer 15, as shown in FIG. 2H, or extends further into the protruding structure Q, as shown in FIGS. 4A and 4B.

The upper select channel structure 16 has the biggest dimension in the upper select gate layer 14, i.e., the dimension of the portion of the upper select channel structure 16 in the upper select gate layer 14 in a first direction x (e.g., the width) is larger than the dimension of any other portion of the upper select channel structure 16 in the first direction x (e.g., the width). The first direction x may be the extending direction of the stack of layers 11 and perpendicular to the stacking direction z of the stack of layers 11.

It is to be noted that, with continuous reference to FIG. 2J and FIG. 3C (an enlarged structural diagram of the part M3 in FIG. 2J), since the top of the protruding structure Q has a protruding shape, the formation of the upper select gate layer 14 may be directly or indirectly influenced by the protruding shape. For example, the upper select gate layer 14 includes a second surface cc that is close to the first surface aa and has a recessed region at a position corresponding to the protruding structure Q. The recessed region of the second surface cc is recessed from the first surface aa toward the direction pointing to the second surface cc. That is, the protruding shape of the top of the protruding structure Q transfers to the upper select gate layer 14, so that the upper select channel structure 16 in the upper select gate layer 14 forms an angle α with respect to the surface of the upper select gate layer 14 on the side close to the stack of layers 11 with the angle α being a right angle or an obtuse angle. That is, the angle α between the surface of the upper select gate layer 14 on the side close to the stack of layers 11 and the insulating layer 161 in upper select gate layer 14 is not less than 90°, as shown in FIG. 3C. As a result, sharp corners (acute angles) can be prevented from being formed by the upper select channel structure 16 and the upper select gate layer 14, or else the acute angles may cause local electric field or voltage with too high a magnitude, which may lead to the problem of potential drift.

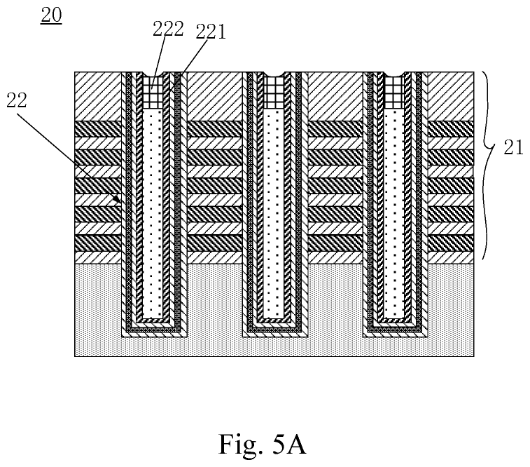

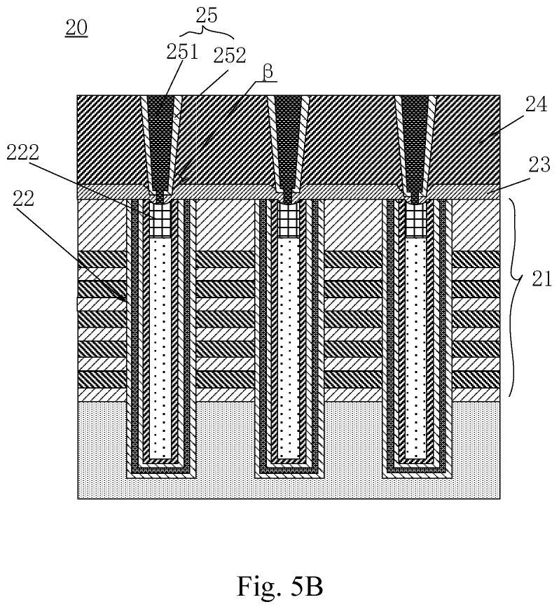

In other implementations, with reference to FIGS. 5A and 5B, which are cross-sectional structural diagrams of another semiconductor structure 20 provided in an example of the present disclosure, the semiconductor structure 20 includes a stack of layers 21, a channel structure 22 extending through the stack of layers 21 in the stacking direction, an etch stop layer 23 located on the stack of layers 21 and covering the channel structure 22, an upper select gate layer 24 on the side of etch stop layer 23 away from the stack of layers 21 and an upper select channel structure 25 extending through the upper select gate layer 24 and the etch stop layer 23, where the channel structure 22 includes a channel layer 221 and a plug structure 222 electrically connected with the channel layer 221, the upper select channel structure 25 includes a conductive layer 251 and an insulating layer 252 surrounding the conductive layer 251, the plug structure 222 is located at the side of the channel structure 22 close to the etch stop layer 23, and the conductive layer 251 in the upper select channel structure 25 extends to and is electrically connected with the plug structure 22.

It can be seen from the above-mentioned operation S101 that when the plug structure 222 is formed, the wet etching in the CMP process causes a recess at the top end of the plug structure 222 and the recess may be transferred to the etch stop layer 23, so that a recess is formed at the top surface of the etch stop layer 23 and a protrusion toward the plug structure 222 is formed at the bottom of the etch stop layer 23. The upper select gate layer 24 is further influenced by the recess at the top surface of the etch stop layer 23, so that a protrusion toward the plug structure 222 is formed at the bottom surface of the upper select gate layer 24 and in turn the angle β between the upper select channel structure 25 and the bottom surface of the upper select gate layer 24 is an acute angle less than 90°, i.e. leads to a sharp corner. Once subsequent voltages are applied on the upper select gate layer 24, sources or drains, concentrated electric field of a relatively large magnitude may occur at the sharp corner, leading to potential drift and leaving the technical problem focused by the present disclosure unsolved. Furthermore, neither the etch stop layer 23 nor the insulating layer 252 has a large thickness and as a result it is easy for the local electric field with a relatively large magnitude at the sharp corner to cause breakdown of the etch stop layer 23 and the insulating layer 252 and in turn to influence the performance of memory.

However, the semiconductor structure 10 in examples of the present disclosure can solve at least in part the above-mentioned problem. With continuous reference to FIGS. 21 and 4C, after formation of the plug structures 122, oxidization is performed at the top surface of the plug structure 122 to form protruding structure Q with an expanded volume, which changes the top of the plug structure 122 from having a recess shape to having a protrusion shape. As such, when the upper select gate layer 24 is formed subsequently, the protrusion shape may influence the bottom surface of the upper select gate layer 24 directly or indirectly, i.e., make the bottom surface thereof recessed toward the direction away from the stack of layers 11, so that the upper select channel structure 16 forms an angle α with respect to the bottom surface of the upper select gate layer 14 with the angle α being a right angle or an obtuse angle rather than an acute angle β as shown in FIG. 5B. Therefore, local electric field or voltage with a relatively large magnitude that may be caused by sharp corners, which leads to the technical problems of potential drift and breakdown of the etch stop layer 15 and the insulating layer 161, can be avoided as much as possible.

It is to be noted that, with continuous reference to FIGS. 2J and 2K or FIGS. 4B and 4C (wherein FIG. 4C is another cross-sectional structural diagram of the semiconductor structure 10 provided in examples of the present disclosure), after the above-mentioned operation S104, gate line slits may be formed and gate replacement can be performed through the gate line slits to obtain gate layers 110a as substitutes for the gate sacrificial layers 111. After the gate replacement, the stack of layers 11 is changed into the stack structure 11a.

Examples of the present disclosure further provide a semiconductor structure 10. With continuous reference to FIGS. 2K and 4C, the semiconductor structure 10 includes a stack structure 11a; a channel structure 12 extending through the stack structure 11a in the stacking direction z, the channel structure 12 including a channel layer 121 and a plug structure 122 electrically connected with the channel layer 121, and the plug structure 122 being located at a side of the channel layer 121; a protruding structure 17 being located on the side of the plug structure 122 away from the channel layer 121 and protruding toward the direction away from the plug structure 122; an upper select gate layer 14 located on the side of the stack structure 11a close to the plug structure 122 and covering the protruding structure 17; and an upper select channel structure 16 extending through the upper select gate layer 14 and to the plug structure 122 in the stacking direction z.

Herein, the channel layer 121 includes polysilicon and the plug structure 122 includes a conductive material, for example, any one or combination of polysilicon and metal materials such as tungsten, cobalt, copper, or aluminum. The stack structure 11a includes alternating gate layers 111a and gate insulating layers 112 and the stacking direction z is the direction, in which the gate layers 111a and the gate insulating layers 112 are stacked. The gate layers 111a include polysilicon, tungsten, copper, or the like. The upper select gate layer 14 includes polysilicon or the like.

In some implementations, with continuous reference to FIG. 2K, the semiconductor structure 10 further includes an etch stop layer 15 located on the side of the stack structure 11a close to the plug structure 122, the upper select gate layer 14 is located on the side of the etch stop layer 15 away from the stack structure 11a, and the protruding structure 17 includes the portion of the etch stop layer 15 corresponding to the plug structure.

Herein, the etch stop layer 15 may include an insulating material such as silicon protruding structure and is different from the material of the upper select gate layer 14. In the stacking direction z, the thickness of the etch stop layer 15 is relatively small, e.g., smaller than any one of the thickness of the upper select gate layer 14 and the thickness of the top gate insulating layer 112.

In some other implementations, the protruding structure 17 may include the protruding structure Q (e.g., as shown in FIG. 4C) or may further include the etch stop layer 15 between the protruding structure Q and the upper select gate layer 14, i.e., the portion of the etch stop layer 15 corresponding to the plug structure 122 (e.g., as shown in FIG. 2K).

In some implementations, the surface of the protruding structure 17 on the side away from the plug structure 122 forms an angle not less than 90° with respect to the upper select channel structure 16 in the upper select gate layer 14.

In some implementations, the upper select channel structure 16 includes a conductive layer 162 and an insulating layer 161 surrounding the conductive layer 162 and the surface of protruding structure 17 on the side away from the plug structure 122 forms an angle not less than 90° with respect to the insulating layer 161 in the upper select gate layer 14.

Herein, the insulating layer 161 may include protruding structure such as silicon protruding structure and the conductive layer 162 may be any one or combination of tungsten, cobalt, copper, aluminum, silicon or doped crystalline silicon.

In some implementations, each conductive layer 162 extends through the upper select gate layer 14 and the protruding structure 17 and to the plug structure 122 in the stacking direction z and the insulating layer 161 extends through the upper select gate layer 14 in the stacking direction z and to be connected with the protruding structure 17.

In some implementations, the dimension of the portion of the upper select channel structure 16 in the upper select gate layer 14 in a first direction x (e.g., the width) is larger than the dimension of other portion of the upper select channel structure 16 in the first direction x (e.g., the width). The first direction x may be the extending direction of the stack of layers 11 and perpendicular to the stacking direction z of the stack structure 11a.

In some implementations, the channel structure 12 further includes a memory functional layer 124 and a filling layer 123; the channel layer 121 surrounds the filling layer 123 and the memory functional layer 124 surrounds the channel layer 121; and the spacing between the surface of the memory functional layer 124 on the side close to the upper select gate layer 14 and the surface of the upper select gate layer 14 on the side away from the stack structure 11a is smaller than the spacing between the surface of the filling layer 123 on the side close to the upper select gate layer 14 and the surface of the upper select gate layer 14 on the side away from the stack structure 11a.

Herein, the memory functional layer 124 may be an ONO film including silicon protruding structure, silicon nitride and silicon protruding structure. The spacing between the surface of the plug structure 122 on the side close to the upper select gate layer 14 and the surface of the upper select gate layer 14 on the side away from the stack structure 11a is larger than the spacing between the surface of the memory functional layer 124 on the side close to the upper select gate layer 14 and the surface of the upper select gate layer 14 on the side away from the stack structure 11a.

In some implementations, the spacing between the surface of the protruding structure 17 on the side close to the upper select gate layer 14 and the surface of the plug structure 122 on the side close to the upper select gate layer 14 is larger than the spacing between the surface of the memory functional layer 124 on the side close to the upper select gate layer 14 and the surface of the plug structure 122 on the side close to the upper select gate layer 14.

In some implementations, the surface of the upper select gate layer 14 on the side close to the stack structure 11a includes a recessed region corresponding to the protruding structure 17, with the recessed region being recessed toward the side away from the stack structure 11a.

It should be understood that for the structures and fabrication processes of the components of the semiconductor structure 10 in examples of the present disclosure, refer to the examples of the fabrication method of the semiconductor structure 10 described above and no repetitions will be made here.

In summary, in the fabrication method of a semiconductor structure 10 and the semiconductor structure 10 provided in examples of the present disclosure, a stack of layers 11 and a channel structure is formed, with the stack of layers 11 including a first surface aa and the channel structure 12 extending through the stack of layers 11 in the stacking direction z and including a channel layer 121 and a plug structure 122 electrically connected with the channel layer 121; the plug structure 122 is located at the side of the channel layer 121 close to the first surface aa and has an exposed surface bb; the exposed surface bb is oxidized to form protruding structure Q thereon and the surface of the protruding structure Q on the side away from the plug structure 122 protrudes above the first surface aa; an upper select gate layer 14 is formed on the first surface aa and covers the protruding structure Q; an upper select channel structure 16 is formed that extends through the upper select gate layer 14 and to the plug structure 122 in the stacking direction z, so that sharp corners are prevented from being formed by the upper select channel structure 16 in the upper select gate layer 14 and the bottom surface of the upper select gate layer 14 and in turn the problem of potential drift caused by local electric field with too large a magnitude can be solved, which is beneficial to reliability of the memory.

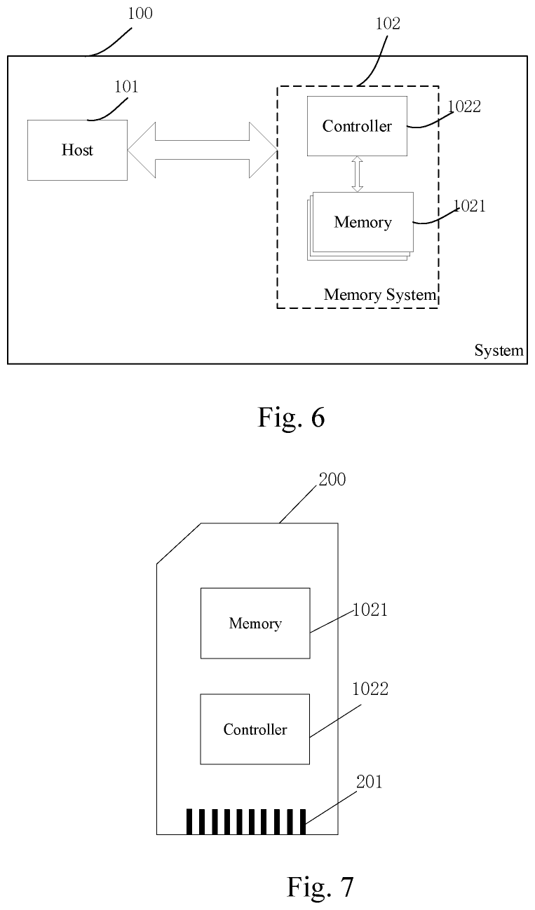

Furthermore, refer to FIG. 6, which is a structural diagram of an example system 100 provided in an example of the present disclosure. The system 100 can be a mobile phone, a desktop computer, a laptop computer, a tablet, a vehicle computer, a gaming console, a printer, a positioning device, a wearable electronic device, a smart sensor, a virtual reality (VR) device, an augmented reality (AR) device, or any other suitable electronic devices having storage devices therein. As shown in FIG. 6, the system 100 may include a host 101 and a memory system 102 including one or more memories 1021 and a controller 1022. The host 101 may be a processor of an electronic device, such as a central processing unit (CPU) or a system-on-chip (SOC) (e.g., an application processor (AP)). The host 101 may be configured to send data to the memory 1021 or receive data from the memory 1021.

In examples of the present disclosure, the memory 1021 is not limited to a 3D NAND memory and can be implemented as any one of various other non-volatile memories that are capable of maintaining the data stored therein when power is off, without departing from the disclosure or teaching of the present disclosure.

In some implementations, the controller 1022 is coupled to the memory 1021 and the host 101 and configured to control the memory 1021, e.g., to control the data write and read operations of the memory 1021. The controller 1022 can manage the data stored in the memory 1021 and communicate with the host 101. In some implementations, the controller 1022 is designed to operate in a low duty-cycle environment like a secure digital (SD) card, a compact flash (CF) card, a universal serial bus (USB) flash drive or any other medium for use in an electronic device such as a personal computer, a digital camera, a mobile phone, etc. In some implementations, the controller 1022 is designed to operate in a high duty-cycle environment like a solid state disk (SSD) or an embedded multi-media-card (eMMC), used as a data storage device for a mobile device such as a smart phone, a tablet computer or a laptop computer and an enterprise storage array.

The controller 1022 can be configured to control operations of the memory 1021, such as read, erase, and program operations. The controller 1022 can also be configured to manage various functions with respect to the data stored or to be stored in the memory 1021, including, but not limited to, bad-block management, garbage collection, logical-to-physical address conversion, wear leveling and the like. In some implementations, the controller 1022 is further configured to process error correcting codes (ECCs) with respect to the data read from or written to the memory 1021. Any other suitable functions can be performed by the controller 1022 as well, for example, formatting the memory 1021. The controller 1022 can communicate with an external device (e.g., the host 101) according to a particular communication protocol. For example, the controller 1022 may communicate with an external equipment through at least one of various interface protocols, such as a USB protocol, an MMC protocol, a peripheral component interconnection (PCI) protocol, a PCI-express (PCIE) protocol, an advanced technology attachment (ATA) protocol, a serial-ATA protocol, a parallel-ATA protocol, a small computer system interface (SCSI) protocol, an enhanced small drive interface (ESDI) protocol, an integrated drive electronic (IDE) protocol, a Firewire protocol, etc.

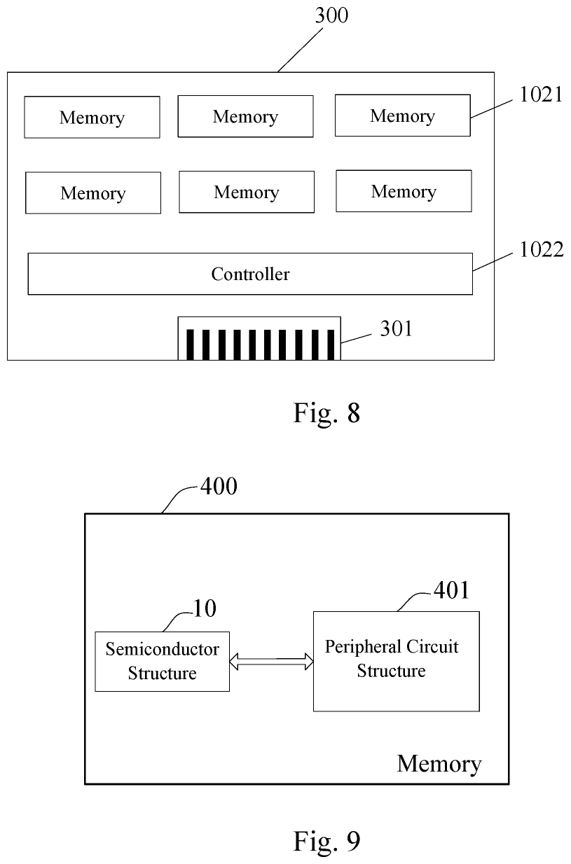

The controller 1022 and the one or more memories 1021 can be integrated into various types of storage devices, for example, be included in the same package, such as an universal flash storage (UFS) package or an eMMC package. That is, the memory system 102 can be implemented and packaged into different types of electronic products. In an example as shown in FIG. 7, the controller 1022 and a single memory 1021 can be integrated into a memory card 200. The memory card 200 may include a PC card (PCMCIA, personal computer memory card international association), a CF card, a smart media (SM) card, a memory stick, a multimedia card (MMC, RSMMC, MMCmicro), an SD card (SD, miniSD, microSD, SDHC), a UFS, etc. The memory card 200 may further include a memory card connector 201 coupling the memory card 200 with a host (e.g., the host 101 in FIG. 6). In another example as shown in FIG. 8, the controller 1022 and multiple memories 1021 can be integrated into an SSD 300. The SSD 300 may further include an SSD connector 301 coupling the SSD 300 with a host (e.g., the host 101 in FIG. 6). In some implementations, at least one of the storage capacity or the operation speed of the SSD 300 is greater than those of the memory card 200.

FIG. 9 is a structural diagram of a memory 400 provided in an example of the present disclosure. The memory 400 includes any semiconductor structure 10 described above and a peripheral circuit structure 401 coupled with the semiconductor structure 10 and the peripheral circuit structure 401 may be configured to perform read, write, erase, verify and any other operations on the semiconductor structure 10.

In some implementations, the peripheral circuit structure 401 may further include a word line driver, a bit line driver, a column decoder, a sense circuit, a data buffer, a program verify logic, an erase verify circuit and the like, which can perform the above-mentioned operations according to the acquired computer program instructions. It is noted that the peripheral circuit structure 401 and the semiconductor structure 10 may be arranged in a stack or side by side, without limitation here.

What have been described above are only examples of the present disclosure and not intended to limit the present disclosure. Any modifications, equivalent substitutions and improvements made within the spirit and principle of the present disclosure should be covered by the scope of the present disclosure.

What is claimed is:

1. A method of fabricating a semiconductor structure, comprising:
forming a stack of layers having a first surface;
forming a channel structure extending through the stack of layers in a stacking direction, and comprising a channel layer and a plug structure electrically connected with the channel layer, wherein the plug structure is located close to the first surface and comprising an exposed surface;
oxidizing the exposed surface of the plug to form a protruding structure, a surface of the protruding structure protruding above the first surface;
forming an upper select gate layer on the first surface, the upper select gate layer covering the protruding structure; and
forming an upper select channel structure extending through the upper select gate layer and the protruding structure in the stacking direction, and being in contact with the plug structure.

2. The method of claim 1, wherein the upper select gate layer comprises a recessed region corresponding to a position of the protruding structure.

3. The method of claim 2, further comprising:
before formation of the upper select gate layer, forming an etch stop layer on the first surface to cover the protruding structure,
wherein the upper select gate layer is formed on the etch stop layer away from the stack of layers.

4. The method of claim 3, wherein the etch stop layer comprises:
a recess portion in contact with the protruding structure; and
a protrude portion in contact with the recessed region of the upper select gate layer.

5. The method claim 1, wherein an angle between the upper select channel structure in the upper select gate layer and a surface of the upper select gate layer close to the protruding structure is not less than 90°.

6. The method claim 1, further comprising, before oxidization of the exposed surface, doping the exposed surface.

7. The method of claim 1, wherein forming the upper select channel structure comprises:
forming, using a first etching, a first hole extending through the upper select gate layer in the stacking direction;
forming an insulating layer over an inner wall of the first hole;
forming, using a second etching and through the first hole, a second hole extending through the upper select gate layer, the insulating layer and the protruding structure to expose the plug structure; and
filling a conductive layer in the first hole and the second hole to form the upper select channel structure.

8. The method of claim 7, wherein an angle between a surface of the upper select gate layer close to the protruding structure and the insulating layer in the upper select gate layer is not less than 90°.

9. The method of claim 1, wherein forming the channel structure comprises:
forming a memory channel structure extending through the stack of layers in the stacking direction, the memory channel structure comprising the channel layer and a filling layer surrounded by the channel layer;
removing a portion of the filling layer close to the first surface in the memory channel structure to form a space;
forming a layer of conductive material on the first surface and filling the space; and
removing a portion of the conductive material outside the space to form the plug structure.

10. The method of claim 9, wherein forming the memory channel structure comprises:
forming a memory channel hole extending through the stack of layers in the stacking direction;
forming a memory functional layer on an inner wall of the memory channel hole;
forming the channel layer on the memory functional layer; and
forming the filling layer on the channel layer to fill the memory channel hole.

11. A semiconductor structure, comprising:
a stack structure having a first surface;
a channel structure extending through the stack structure in a stacking direction, and comprising a channel layer and a plug structure electrically connected with the channel layer, wherein the plug structure is located close to the first surface;
a protruding structure located on the plug structure protruding above the first surface away from the plug structure;
an upper select gate layer located on the first surface of the stack structure and covering the protruding structure; and
an upper select channel structure extending through the upper select gate layer and the protruding structure in the stacking direction, and being in contact with the plug structure.

12. The semiconductor structure of claim 11, wherein the upper select gate layer comprises a recessed region corresponding to a position of the protruding structure.

13. The semiconductor structure of claim 12, further comprising:
an etch stop layer between the protruding structure and the upper select gate layer.

14. The semiconductor structure of claim 13, wherein the etch stop layer comprises:
a recess portion in contact with the protruding structure; and
a protrude portion in contact with the recessed region of the upper select gate layer.

15. The semiconductor structure of claim 11, wherein the upper select channel structure comprises:
a conductive layer; and
an insulating layer surrounding the conductive layer,
wherein an angle between a surface of the upper select gate layer close to the protruding structure and the insulating layer in the upper select gate layer is not less than 90°.

16. The semiconductor structure of claim 15, wherein the conductive layer extends through the upper select gate layer, the insulating layer, and the protruding structure in the stacking direction, and is in contact with the plug structure.

17. The semiconductor structure of claim 11, wherein the channel structure further comprises:
a memory functional layer; and
a filling layer;
wherein the channel layer surrounds the filling layer, and the memory functional layer surrounds the channel layer.

18. A memory system, comprising:
a memory device, comprising:
a stack structure having a first surface;
a channel structure extending through the stack structure in a stacking direction, and comprising a channel layer and a plug structure electrically connected with the channel layer, wherein the plug structure is located close to the first surface;
a protruding structure located on the plug structure protruding above the first surface away from the plug structure;
an upper select gate layer located on the first surface of the stack structure and covering the protruding structure; and
an upper select channel structure extending through the upper select gate layer and the protruding structure in the stacking direction, and being in contact with the plug structure; and
a controller coupled with the memory device and configured to control the memory device to store data.

19. The memory system of claim 18, wherein the upper select gate layer comprises a recessed region corresponding to a position of the protruding structure.

20. The memory system of claim 19, further comprising:
an etch stop layer between the protruding structure and the upper select gate layer, the etch stop layer comprises:
a recess portion in contact with the protruding structure; and
a protrude portion in contact with the recessed region of the upper select gate layer.
